(19) United States
(12) Patent Application Publication
(10) Pub. No.: US 2024/0124297 A1
(43) Pub. Date: Apr. 18, 2024

(54) CARTRIDGE INTERFERENCE

(71) Applicant: VueReal Inc., Waterloo (CA)

(72) Inventors: Gholamreza CHAJI, Waterloo (CA); Ehsanollah FATHI, Waterloo (CA); Hossein Zamani SIBONI, Waterloo (CA); Dana Saud Yousef AYYASH, Waterloo (CA)

(73) Assignee: VueReal Inc., Waterloo, ON (CA)

(21) Appl. No.: 18/547,022

(22) PCT Filed: Feb. 22, 2022
(86) PCT No.: PCT/CA2022/050249

§ 371 Date: Aug. 18, 2023

Related U.S. Application Data
(60) Provisional application No. 63/151,992, filed on Feb. 22, 2021.

(51) Int. Cl. B81B 7/02; B81C 1/00

(52) U.S. Cl. CPC B81B 7/02; B81C 1/00341; B81B 2203/0307; B81B 2203/0315

(57) ABSTRACT

The present disclosure relates to transfer of a selected set of microdevices from a donor substrate to a receiver/system substrate while there can be already microdevices transferred in the system substrate. In particular the invention deals with methods to transfer microdevices to a system substrate that do not damage already transferred microdevices, by using donor substrate heights, cavities and use of sacrificial layers.

### FIELD OF THE INVENTION

The present disclosure relates to transfer of a selected set of microdevices from a donor substrate to a receiver/system substrate while there can be already microdevices transferred in the system substrate.

### BRIEF SUMMARY

According to one of the embodiments, there is a method to transfer microdevices the method comprising, forming a buffer layer on a donor substrate, having microdevices located on a top of the buffer layer, having a system substrate with transferred microdevices on pads, having other pads on the system substrate without microdevices, bringing the donor and system substrate closer such that selected microdevices to be transferred are closure to associated pads on the system substrate, and preventing the donor substrate from touching microdevices on pads on the system substrate with a buffer layer height.

According to another embodiment, there is a method to transfer microdevices the method comprising, forming a buffer layer on a donor substrate, forming cavities in the buffer layer covered by a surface layer, having microdevices located on a top of the buffer layer, having a system substrate with transferred microdevices on pads inside an area associated with a current transfer, having other pads on the system substrate without microdevices, bringing the donor and system substrate closer such that selected microdevices to be transferred are closure to associated pads on the system substrate, and exposing the cavity after a microdevice is transferred by removing the surface layer.

### BRIEF DESCRIPTION OF THE DRAWINGS

The foregoing and other advantages of the disclosure will become apparent upon reading the following detailed description and upon reference to the drawings.

FIG. 1A shows non-flatness of donor/cartridge substrate or system substrate.

FIG. 1B shows selected microdevices are touching or getting close to the selected pads.

FIG. 2A shows the donor substrate has a buffer layer.

FIG. 2B shows the donor and receiver substrates are brought close to each other.

FIG. 3A shows a sacrificial layer formed on top of the microdevice.

FIG. 3B shows the microdevices are transferred into the system substrate with the sacrificial layer removed.

FIG. 3C shows the donor substrate and system substrate brought closer together, and the microdevices are aligned with the associated pads.

FIG. 4A shows a second set of microdevices being transferred to the system substrate that is taller than the microdevices transferred into the substrate.

FIG. 4B shows the donor substrate and system substrate brought closer together, and the microdevices are aligned with the associated pads.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

The invention relates to transfer of a selected set of microdevices from a donor substrate to a receiver/system substrate while there may already be microdevices transferred in the system substrate. In another case, other structures may exist in the receiver substrate that may interfere with the transfer of microdevices. In this invention, previously transferred microdevices are used to explain the invention, however similar topics can be applied to the other structures. Microdevices can be microLED, OLED, microsensors, MEM's, and any other type of devices.

In one case, the microdevice has a functional body and contacts. The contacts can be electrical, optical or mechanical contacts.

In the case of optoelectronic microdevices, the microdevice can have functional layers and charge carrying layers. Where charge carrying layers (doped layers, ohmics and contacts) transfer the charges (electron of hole) between the functional layers and contacts outside the device. The functional layers can generate electromagnetic signals (e.g. lights) or absorb electromagnetic signals.

System substrates may have pixels and pixel circuits such that each pixel controls at least one microdevice. Pixel circuits may be made of electrodes, transistors, or other components. The transistors may be fabricated with a thin film process, CMOS, or organic materials.

Generally, the donor substrate is larger than the area that has microdevices. The challenge is that during a transfer of microdevices, the extended substrate can hit the already transferred microdevices adjacent to the current area and damage existing microdevices. This issue can be aggravated by non-flatness of donor/cartridge substrate or system substrate. Furthermore, the two substrates may not be perfectly parallel.

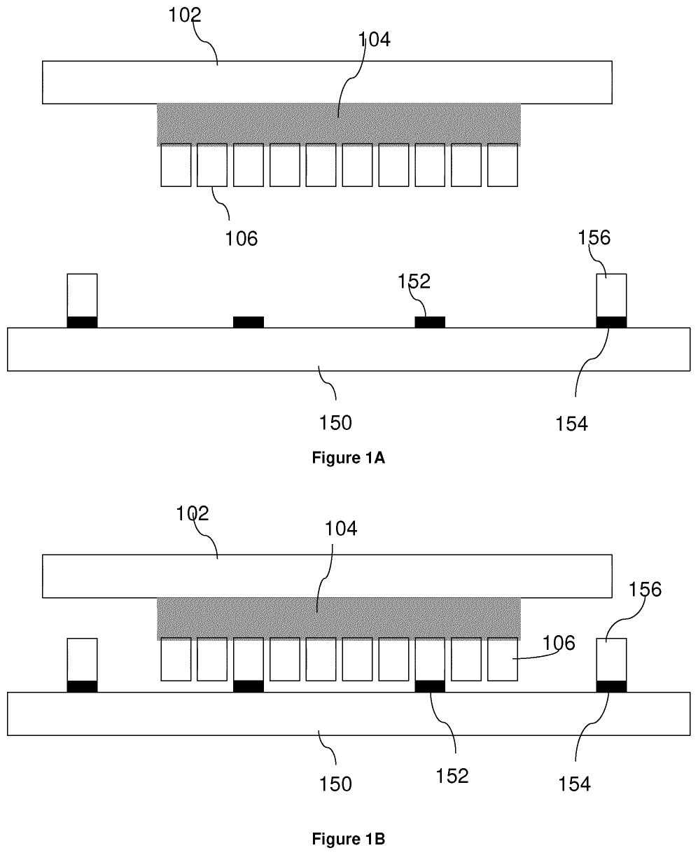

FIGS. 1(1A and 1B) shows an embodiment addressing this issue. Here, as shown in FIG. 1A, a buffer layer 104 is formed on the donor substrate 102 and microdevices 106 are located on top of the buffer layer. The buffer layer can be formed by a patterning or an etching process. It can be polymer, dielectric, or other materials such as metals. Due to the use of semiconductor processes to develop the buffer layer 104, it can be aligned to the edge of the last microdevices on the donor substrate. The system substrate 150 has pads 152 associated with the current microdevices to be transferred to the system substrate 150 from the donor substrate 102. The system substrate 150 also has pads 154 that have already been populated with microdevices 156 and some of these pads may be adjacent to the current location for the transfer.

As demonstrated in FIG. 1B, when the donor substrate 102 and system substrate 152 get close to each other, the selected microdevices are touching or getting close to the selected pads 152. As can be seen the buffer layer prevents the substrate 102 touching the transferred microdevices 156. The height of the buffer layer may be larger than the sum of the surface non-uniformities, parallel error between the two substrates, and difference between the height of transferred microdevices and the currently selected for transfer. There can be other layers (release layers, bonding layers, anchors, etc.) between the microdevices 106 and buffer layer 104.

In one case, the buffer layer is formed on top of the microdevices and then transferred to the donor substrate.

In another case, the buffer layer is part formed on the top of the donor substrate and the microdevices are bonded to the buffer layer. There can be other layers between buffer layers and microdevices such as passivation, anchors, and so on.

In another related case, there may be another layer between the buffer layer and microdevices such as an activity structure.

In another related case, the buffer layer can be etched in the donor substrate. In this case, a mask can form on top of the area with the microdevices, and an etching process is used to form the buffer layer. Etching can be either dry etch or wet etch.

Another challenge in using donor substrates is that there can be microdevices in the same area that are intended to transfer a new set of microdevices. For example, while transferring green microLED there can be red microLED's that are already transferred into the substrate. As a result, the new transfer set can damage the existing microdevices transferred in the substrate.

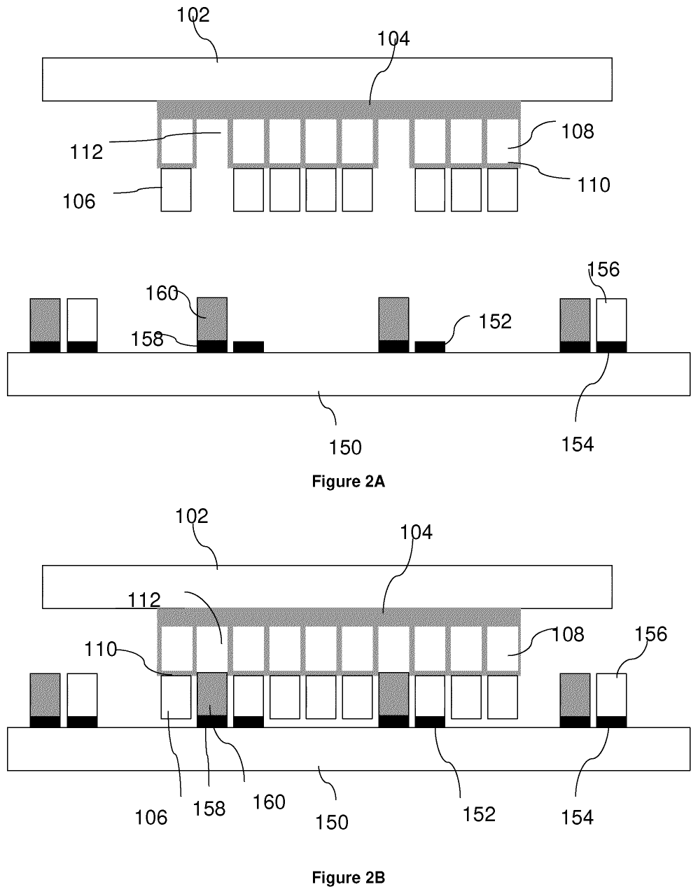

FIGS. 2(2A and 2B) shows a related embodiment addressing the interference with existing microdevices in the same location.

As shown in FIG. 2A, the donor substrate 102 can have a buffer layer 104 similar to the previous structure. Cavities 108 can be formed in the buffer layer or a different structure than the buffer layer (microdevices 106 are located on top of the buffer layer). A surface layer 110 covers the cavity. This surface layer can include functions such as anchors, release layer(s) and so on. A system substrate 150 has pads 152 related to the current set of microdevices that are going to be transferred to the system substrate. The system substrate also has pads 154, outside the area associated with the current transfer and populated with microdevices 156. The system substrate also has pads 158 inside the area associated with the current transfer that are populated with microdevices 160. These microdevices can be different types compared to the ones that are going to be transferred in the current transfer cycle. In the donor substrate, when a microdevice is removed by transfer or other means, the surface layer 110 is also removed exposing the cavity area 108 (the exposed cavity 112 can be seen in the area where the microdevice is removed).

As shown in FIG. 2B the donor and receiver substrates are brought close to each other so that the intended microdevices are put on the pads 152 dedicated for this current transfer. The already transferred microdevices 160 goes to the exposed cavity 112 and therefore will not be damaged by extra pressure.

One method of developing the cavity is to form a sacrificial layer in the shape of the cavities and form the surface layer 110 and buffer layer 104. After or before integrating the microdevices and donor substrate, the sacrificial layer is removed. Another method is to form the buffer layer 104, etch the cavity 112 out of the buffer layer and develop the surface layer 110.

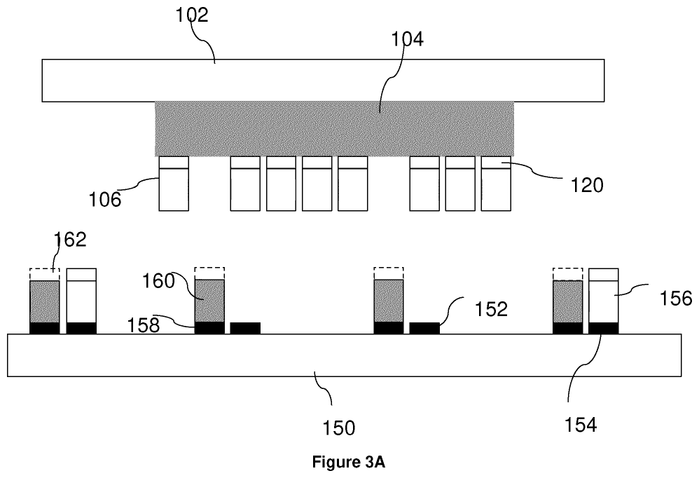

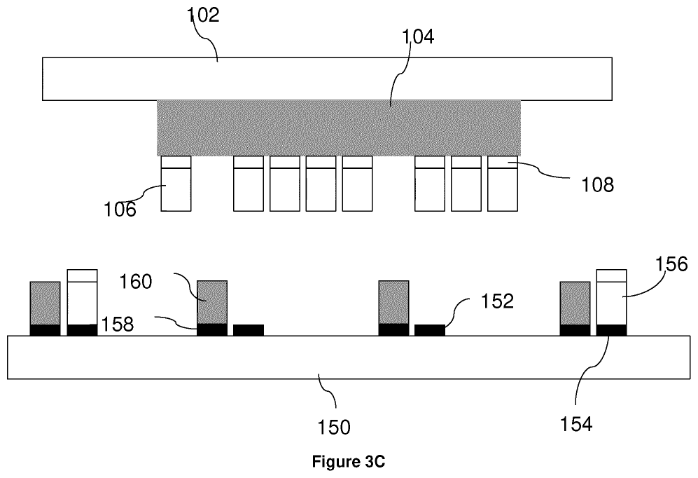

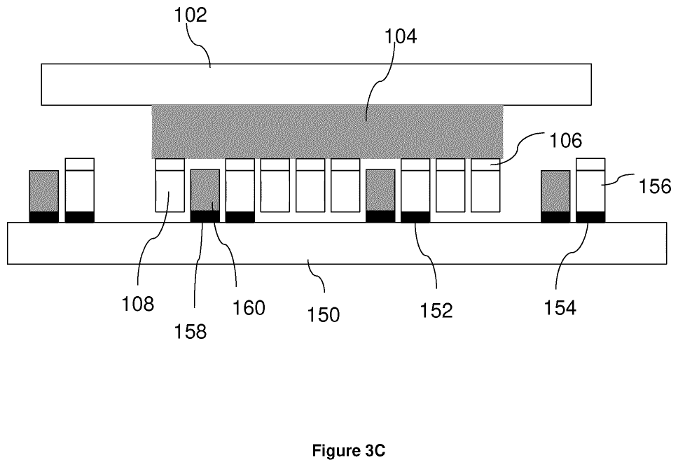

In another related method demonstrated in FIG. 3A, a sacrificial layer 120 is formed on top of the microdevice. After transferring the microdevice into the system substrate the sacrificial layer is removed leading to a shorter structure. A donor substrate 102 may have a buffer layer 104 (the buffer layer may include some other functional layer such as release layer, anchor, inspection and so on). The microdevice 106 on the donor substrate has a sacrificial layer 120. A system substrate 150 has pads 152 related to the current set of microdevices that are going to be transferred to the system substrate. The system substrate also has pads 154 populated with microdevices 156 outside the area associated with the current transfer. The system substrate also has pads 158 inside the area associated with the current transfer that are populated with microdevices 160. These microdevices can be different types compared to the ones that are going to be transferred in the current transfer cycle.

As shown in FIG. 3B, after the microdevices 160 are transferred into the system substrate, the sacrificial layer 162 (as shown in FIG. 3A) is removed. The sacrificial layer can be polymer, dielectric, metallic or other materials. The sacrificial layer can be removed by dry etching, different plasma, or wet etch, lights/laser or thermal process. In one related case, a polymer is used that is decomposed under thermal conduction, under some lighting conditions or under plasma. As a result, the microdevices transferred to the system substrate will be effectively shorter than the microdevices not transferred into the system substrate. The process of removing the sacrificial layer can be done during transfer or after transferring microdevices into the system substrate.

As shown in FIG. 3C, the donor substrate 102 and system substrate 150 are brought closer together, and the microdevices that are set to be transferred are aligned with the associated pads 152. As can be seen the microdevice 160 and the donor substrate 102 have a gap so that the existing microdevice 160 on the system substrate does not get damaged. The sacrificial layer can be formed on the microdevices prior to transferring to the donor substrate or it can be formed on the donor substrate. The sacrificial layer can also be part of microdevice layer development.

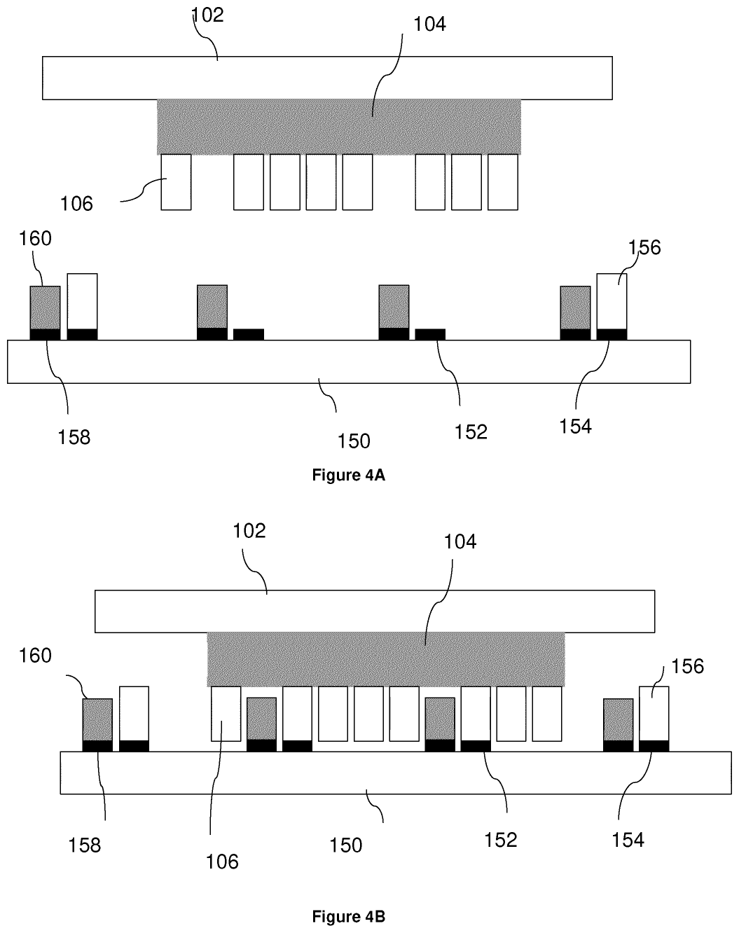

In another related embodiment demonstrated in FIG. 4A, a second set of microdevices is going to be transferred to the system substrate that is taller than the microdevices transferred into the substrate. A donor substrate 102 may have a buffer layer 104 (the buffer layer may include some other functional layer such as release layer, anchor, inspection and so on). The microdevice 106 on the donor substrate can also have a sacrificial layer 120 similar to what presented in FIGS. 3 (3A, 3B and 3C). A system substrate 150 has pads 152 related to the current set of microdevices that are going to be transferred to the system substrate. The system substrate also has pads 154 populated with microdevices 156 outside the area associated with the current transfer. The system substrate 150 also has pads 158 inside the area associated with the current transfer that are populated with microdevices 160. These microdevices can be different types compared to the ones that are going to be transferred in the current transfer cycle.

As shown in FIG. 4B, the donor substrate 102 and system substrate 150 are brought closer together, and the microdevices that are set to be transferred are aligned with the associated pads 152. As it can be seen the microdevice 160 and the donor substrate 102 have a gap so that the microdevice 160 does not get damaged.

In one related case, after the devices are transferred into system substrate, an optical film can be used to embody the microdevices to reduce the effect of the height difference between microdevices and viewing angle.

### Method Aspects

The present disclosure relates to a method to transfer microdevices the method comprising, forming a buffer layer on a donor substrate, having microdevices located on a top of the buffer layer, having a system substrate with transferred microdevices on pads, having other pads on the system substrate without microdevices, bringing the donor and system substrate closer such that selected microdevices to be transferred are closer to associated pads on the system substrate, and preventing the donor substrate from touching microdevices on pads on the system substrate with a buffer layer height.

Herein the height of the buffer layer may be larger than a sum of surface non-uniformities, parallel error between the two substrates, and difference between the height of transferred microdevices and the microdevice selected for transfer. Furthermore, the buffer layer may be formed by a patterning or an etching process and is a polymer, a dielectric or a metal. In addition, the buffer layer may be aligned to an edge of the last microdevices on the donor substrate. Also, the buffer layer may be formed on top of the microdevices and then transferred to the donor substrate.

The method may further comprise the buffer layer being partly formed on the top of the donor substrate and the microdevices are bonded to the buffer layer. Here, there are layers between buffer layers and microdevices such as passivation or anchors.

The method may further comprise having another layer between the buffer layer and microdevices such as a cavity structure.

The method may further have the buffer layer etched in the donor substrate and wherein a mask is formed on top of the area with the microdevices, and an etching process is used to form the buffer layer, wherein etching is either dry etch or wet etch.

Further, in the method a sacrificial layer may be formed on top of the microdevice and after transferring the microdevice into the system substrate the sacrificial layer is removed.

Further, in the method, the microdevices being transferred to the system substrate are taller than the transferred microdevices on the system substrate.

Here, the transferred microdevices on pads are inside an area associated with a current transfer and the system substrate also has pads populated with microdevices outside the area associated with the current transfer and the buffer layer may include functions such as anchors or release layer. Here, the microdevices are of different types compared to the ones being transferred in the current transfer.

Further in the method, after the transfer into the system substrate, the sacrificial layer may be removed.

The present disclosure also relates to a method to transfer microdevices the method comprising, forming a buffer layer on a donor substrate, forming cavities in the buffer layer covered by a surface layer, having microdevices located on a top of the buffer layer, having a system substrate with transferred microdevices on pads inside an area associated with a current transfer, having other pads on the system substrate without microdevices, bringing the donor and system substrate closer such that selected microdevices to be transferred are closer to associated pads on the system substrate, and exposing the cavity after a microdevice is transferred by removing the surface layer.

The method may further have the surface layer include functions such as anchors or a release layer.

Further, the system substrate also has pads populated with microdevices outside the area associated with the current transfer.

Further, the already transferred microdevices may go to the exposed cavity.

Further, a sacrificial layer is formed in a shape of the cavities and also forms the surface layer and the buffer layer. Here, the sacrificial layer is removed after or before integrating the microdevices and donor substrate.

Further in the method, the cavity may be etched out of the buffer layer and the surface layer is developed. Here, the sacrificial layer is removed by dry etching, different plasma, or wet etch.

Further in the method, the sacrificial layer may create a gap between the microdevices inside the area associated with the current transfer and the donor substrate.

Further in the method, the sacrificial layer may be formed on the microdevices prior to transferring to the donor substrate or it can be formed on the donor substrate and wherein the sacrificial layer is formed part of a microdevice layer development.

Further in the method, the microdevices being transferred to the system substrate are taller than the transferred microdevices on the system substrate. Here, the transferred microdevices on pads are inside an area associated with a current transfer and the system substrate also has pads populated with microdevices outside the area associated with the current transfer. Also, the buffer layer may include functions such as anchors, release layer, or inspection and wherein the microdevices are of different types compared to the ones being transferred in the current transfer.

Furthermore, in the method, the taller height of the microdevices being transferred creates a gap between the transferred microdevices inside the area associated with the current transfer and the donor substrate.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to transfer microdevices the method comprising:
forming a buffer layer on a donor substrate;
having microdevices located on a top of the buffer layer;
having a system substrate with transferred microdevices on pads;
having other pads on the system substrate without microdevices;
bringing the donor and system substrate closer such that selected microdevices to be transferred are closer to associated pads on the system substrate; and
preventing the donor substrate from touching microdevices on pads on the system substrate with a buffer layer height.

2. The method of claim 1, where in the height of the buffer layer is larger than a sum of surface non-uniformities, parallel error between the two substrates, and difference between a height of transferred microdevices and the microdevice selected for transfer.

3. The method of claim 1, wherein the buffer layer is formed by a patterning or an etching process and is a polymer, a dielectric or a metal.

4. The method of claim 1, wherein the buffer layer is aligned to an edge of last microdevices on the donor substrate.

5. The method of claim 1, wherein the buffer layer is formed on top of the microdevices and then transferred to the donor substrate.

6. The method of claim 1, wherein the buffer layer is partly formed on the top of the donor substrate and the microdevices are bonded to the buffer layer.

7. The method of claim 6, wherein there are layers between buffer layers and microdevices such as passivation or anchors.

8. The method of claim 1, wherein there is another layer between buffer layer and microdevices such as a cavity structure.

9. The method of claim 1, wherein the buffer layer is etched in the donor substrate.

10. The method of claim 9, wherein a mask is formed on top of the area with the microdevices, and an etching process is used to form the buffer layer, wherein etching is either dry etch or wet etch.

11. (canceled)

12. (canceled)

13. (canceled)

14. (canceled)

15. (canceled)

16. (canceled)

17. (canceled)

18. The method of claim 1, wherein a sacrificial layer is formed on top of the microdevice and after transferring the microdevice into the system substrate the sacrificial layer is removed.

19. The method of claim 18, wherein the transferred microdevices on pads are inside an area associated with a current transfer and the system substrate also has pads populated with microdevices outside the area associated with the current transfer.

20. The method of claim 18, wherein the buffer layer includes functions such as anchors or release layer.

21. The method of claim 19, wherein the microdevices are of different types compared to the ones being transferred in the current transfer.

22. The method of claim 18, wherein after the transfer into the system substrate, the sacrificial layer is removed.

23. The method of claim 22, wherein the sacrificial layer is removed by dry etching, different plasma, or wet etch.

24. The method of claim 19, wherein the sacrificial layer creates a gap between the microdevices inside the area associated with the current transfer and the donor substrate.

25. The method of claim 18 wherein the sacrificial layer is formed on the microdevices prior to transferring to the donor substrate or it can be formed on the donor substrate.

26. The method of claim 18, wherein the sacrificial layer is formed part of a microdevice layer development.

27. The method of claim 1, wherein the microdevices being transferred to the system substrate are taller than the transferred microdevices on the system substrate.

28. The method of claim 27, wherein the transferred microdevices on pads are inside an area associated with a current transfer and the system substrate also has pads populated with microdevices outside the area associated with the current transfer.

29. The method of claim 27, wherein the buffer layer includes functions such as anchors, release layer, or inspection.

30. The method of claim 28, wherein the microdevices are of different types compared to the ones being transferred in the current transfer.

31. The method of claim 27, wherein the taller height of the microdevices being transferred creates a gap between the transferred microdevices inside the area associated with the current transfer and the donor substrate.
